(19) United States
(12) Patent Application Publication
(10) Pub. No.: US 2010/0014353 A1
(43) Pub. Date: Jan. 21, 2010

(54) FLASH MEMORY DEVICE WITH SWITCHING INPUT/OUTPUT STRUCTURE

(76) Inventors: Hsiao-Hua Lu, Chu-Pei City (TW); Chih-Ming Kuo, Chu-Pei City (TW)

Correspondence Address: SCHMEISER, OLSEN & WATTS, 22 CENTURY HILL DRIVE, SUITE 302, LATHAM, NY, 12110, US

(21) Appl. No.: 12/174,094

(22) Filed: Jul. 16, 2008

(51) Int. Cl. G11C 16/04

(52) U.S. Cl. 365/185.05

(57) ABSTRACT

In a flash memory device with switching I/O structure for applying in flash memory products, depending on actual need for input and/or output pins, other pins may be flexibly switched to input, output, or bi-directional pins through software and/or hardware and/or CAM access. Therefore, data input and/or output rate may be changed through switching the I/O structure. Moreover, after the I/O configuration, the switched other pins may start data input/output immediately after the flash memory is started to operate, without the need of waiting for several input/output phases.

### FIELD OF THE INVENTION

The present invention relates to a flash memory, and more particularly to a flash memory device with switching input/output (I/O) structure for applying in flash memory products, so that, depending on actual need for input and/or output pins, other pins may be flexibly switched to input or output or bi-directional pins via software and/or hardware and/or CAM access. As a result, the data input and/or output rate may be changed through switching the I/O structure; and, after the I/O configuration, the switched other pins may immediately start data input/output without the need of waiting for several input/output phases.

### BACKGROUND OF THE INVENTION

A flash memory is a non-volatile memory that can retain the stored formation even when not powered, and has storage characteristics equivalent to a hard disk. Due to these characteristics, the flash memory has become the storage medium for all kinds of portable digital products.

According to the currently available technical skills, the existing flash memory products can only provide fixed number of input/output (I/O) pins, or a small number of I/O structure combinations. Such I/O structure includes input pins, output pins, and bi-directional pins. Generally speaking, the input pins may be treated as control pins, addresses, or data input pins, while the output pins may be treated as data output pins. Generally, the I/O structure refers to data input/output or bi-directional pins.

In system application, in terms of the existing packaging of limited number of I/O pins, different numbers of input pins and I/O pins are required in designing different types of data bus widths or patterns. When viewing from the existing packaging of limited number of I/O pins, the largest possible switching range that can be provided by a general flash memory is between the different I/O structures.

For instance, two I/O pins, say I/O 1 and I/O 2, may be switched to obtain total 16 different I/O structures. This is because each of the I/O pins may be an input pin, an output pin, a bi-directional pin, or an empty pin. Therefore, two I/O pins can have total 4×4=16 types of I/O structures, such as, for example, the I/O structure of (input, output), or (output, input), or (input/input), or (input, bi-directional), or (empty, bi-direction), etc. A higher number of input pins means a wider data input width; a higher number of output pins means a wider data output width; and a higher number of bi-directional pins means a wider data width.

By switching the I/O structure, the flash memory may be configured to meet different system data bus width designs. For a flash memory product having n (input or I/O) pins, the largest possible number of I/O structure combinations thereof shall be 4ⁿ.

Generally speaking, the number of data I/O pins may be the result of multiplying the smallest number of the initial data I/O pins by 2^{k}, where k is a positive integer, and some input pins or empty pins may be configured as data I/O pins. The input pins may also be expanded, and some data I/O pins may be configured as input pins. Every pin may be configured as an input pin, an output in, or a bi-directional pin.

FIG. 1a is a conceptual view showing a flash memory with an I/O structure based on the conventional technique. As shown in FIG. 1a, the flash memory uses a fixed number of pins as I/O pins.

FIG. 1b is a phase sequence diagram showing the data input/output state of the I/O pins of the flash memory of FIG. 1a. As can be seen from FIG. 1b, the I/O pins are controlled by different control phases to serve as input pins or output pins, but other pins that are not I/O pins could not be switched to I/O pins. That is, other pins may not be used as I/O pins. Here, the sequence of input/output phases is that, for example, after two successive input phases, there are two successive output phases. Then, there are still two successive input phases. During the data input/output phases, there is not any signal or action at other pins.

FIG. 2a is a conceptual view showing a flash memory with another I/O structure based on the conventional technique. As shown in FIG. 2a, the flash memory has an I/O pin [0:m] and two other pins [0:m], [m+1 . . . n]. In the I/O structure of the flash memory, during the data output phase, the other pin [0:m] may be configured as a data output pin [m+1:2m+1] through a software instruction.

FIG. 2b is a phase sequence diagram showing the data input/output state of the I/O pins of the flash memory of FIG. 2a. As can be seen from FIG. 2b, after the I/O configuration, the phase sequence includes two successive input phases. During these two successive input phases, the I/O pin [0:m] will input data, while the other pin [0:m] does not act. Then, there is an output phase, during which the other pin [0:m] is configured as an output pin [m+1:2m+1]. Therefore, during the output phase, the data output rate is multiplied.

That is, in the above I/O configuration, during the output phase, the other pin [0:m] may be configured as an output pin [m+1:2m+1] to output data to thereby increase the data output rate. The vector widths [0:m] and [m+1:2m+1] are the same with each other.

However, in the conventional flash memory shown in FIG. 1a, the memory I/O structure could not be changed or switched. And, in the conventional flash memory shown in FIG. 2a, while the I/O structure thereof may be changed or switched during data output, it is impossible to use the switched I/O structure to increase the data input rate during the data input. Moreover, in other conventional flash memories with switching I/O structure, the data input/output does not start immediately after the starting of the flash memory, but will start only after several input/output phases.

Therefore, it would be desirable to enable increased data input rate and increased data output rate during the data input phase and the data output phase, respectively. And, it is also desirable to enable the flash memory with switching I/O structure to start the data input/output immediately after the flash memory is started to operate.

### SUMMARY OF THE INVENTION

A primary object of the present invention is to provide a flash memory device with switching I/O structure for applying in flash memory products, so that, depending on the actual need for input and/or output pins, other pins may be flexibly switched to input, or output, or bi-directional pins via software and/or hardware and/or content addressable memory (CAM) access. With the present invention, the switched other pins may start data input/output immediately after the flash memory is started to operate, without the need of waiting for several input/output phases.

Another object of the present invention is to provide a flash memory device with switching I/O structure for applying in flash memory products, so that, depending on actual need for input and/or output pins, other pins may be flexibly switched to input or output or bi-directional pins via software and/or hardware and/or CAM access. As a result, the data input and/or output rate may be changed through switching the I/O structure.

To achieve the above and other objects, the present invention provides a novel flash memory device with switching I/O structure. Other pins of the flash memory device may be flexibly switched to input, output, or bi-directional pins via software and/or hardware and/or CAM access, so that the data input and/or output rate may be changed through switching the I/O structure. A flash memory device with switching input/output structure comprises at least one memory element, one input, output, or bi-directional pin for inputting/outputting data to/from the flash memory, and at least one other pin that may be an input, an output, or a bi-directional pin wherein other pin may be switched to an input pin, an output pin, a bi-directional pin, or one other pin. The memory element could be a temporary or continuous signal and data storage element. The mentioned flash memory device includes the other pin which could be switched to an input pin, an output pin, a bi-directional pin, or one other pin through software, hardware, or content addressable memory (CAM) access. And the CAM access is to address the memory element in to a plurality of blocks, and utilizes control logic addresses in the memory element corresponded to different blocks. The number of other pins for switching in flash memory device is from 1 to 10. The number of different input/output structures that may be obtained by switching the at least one other pin is the original number of the other pins multiplied by 2n, where n is from −10 to 10; and wherein the data may be input to/output from the flash memory at a rate changeable within a range from 1 to 10 times of an original data input/output rate. At least one other pin may be switched at a frequency of more than one time, and may be switched while the flash memory device is in use or is powered off. This invention further includes a method of automatically switching other pins on a flash memory to input/output pins, comprising the steps of: according to the requirements of a user system to which the flash memory is connected, writing the pin state to be switched to into the flash memory while the flash memory is in a power-off state; and connecting the flash memory to the user system, and, with the pin state to be switched to having been written into the flash memory in advance, the pin is automatically switched to a bus state required by the system device, wherein the other pin may be switched to an input pin, an output pin, a bi-directional pin, or one other pin through software, hardware, or content addressable memory (CAM) access. The CAM access means the memory element is addressed to a plurality of blocks, and the addresses in the memory element are corresponded to different blocks utilizing control logic. The number of other pins for switching is from 1 to 10. And the number of different input/output structures that may be obtained by switching the at least one other pin is the original number of the other pins multiplied by 2n, where n is from −10 to 10; and wherein the data may be input to/output from the flash memory at a rate changeable within a range from 1 to 10 times of an original data input/output rate.

With the present invention, other pins of the flash memory device may be flexibly switched to input, output, or bi-directional pins, and the switched other pins may start data input/output immediately after the flash memory is started to operate, without the need of waiting for several input/output phases.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1a is a conceptual view showing a flash memory with an I/O structure based on the conventional technique;

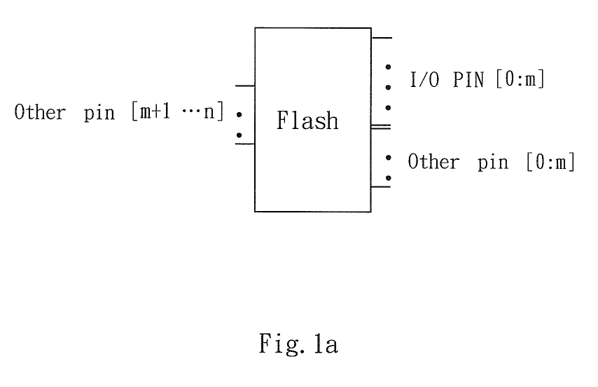

FIG. 1b is a phase sequence diagram for showing data input/output state of the I/O pins of the flash memory of FIG. 1a;

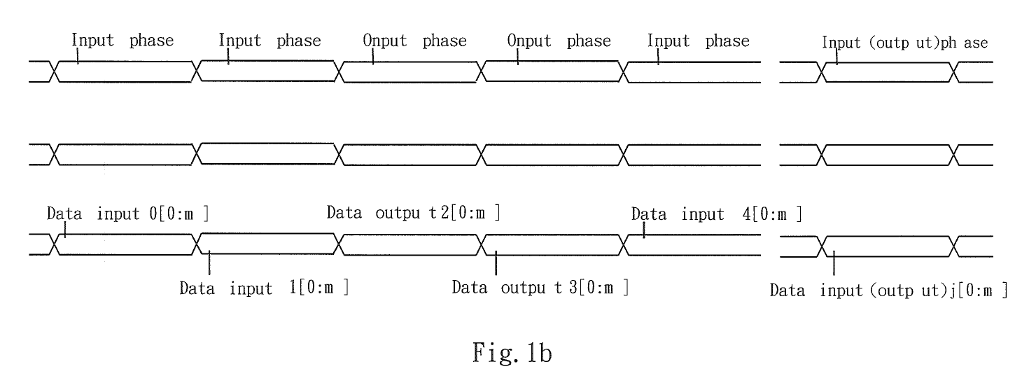

FIG. 2a is a conceptual view showing a flash memory with another I/O structure based on the conventional technique;

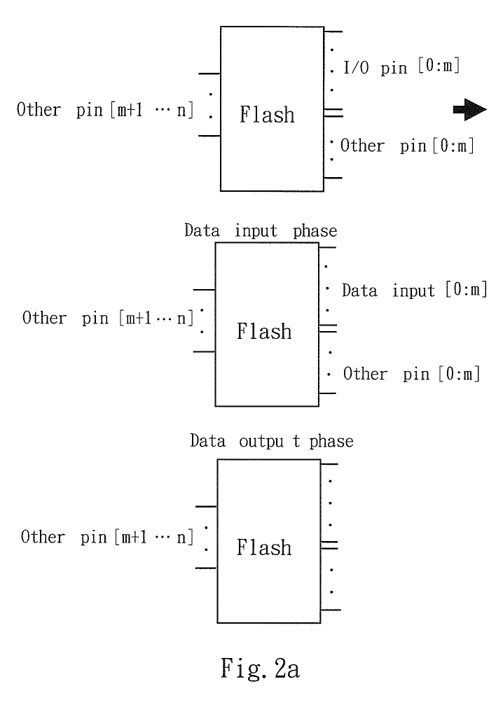

FIG. 2b is a phase sequence diagram for showing data input/output state of the I/O pins of the flash memory of FIG. 2a;

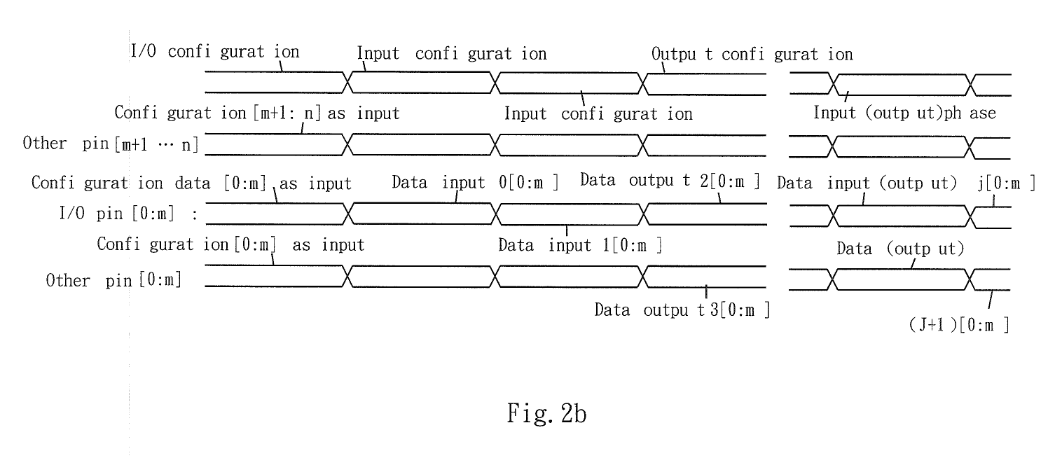

FIG. 3 is a conceptual view showing a flash memory device with switching I/O structure according to a first embodiment of the present invention;

FIG. 4 is a phase sequence diagram showing the data input/output state of the pins of the flash memory device of FIG. 3;

FIG. 5a is a phase sequence diagram showing the switching I/O structure of the flash memory device shown in FIG. 3 is configured through content addressable memory (CAM) access;

FIG. 5b is a phase sequence diagram showing the data input/output state of the pins of the flash memory device with switching I/O structure shown in FIG. 5a;

FIG. 6 is a conceptual view showing a flash memory device with switching I/O structure according to a second embodiment of the present invention;

FIG. 7 is a phase sequence diagram for showing the data input/output state of the pins of the flash memory device shown in FIG. 6;

FIG. 8a is a phase sequence diagram showing the switching I/O structure of the flash memory device shown in FIG. 7 is configured through content addressable memory (CAM) access; and

FIG. 8b is a phase sequence diagram showing the data input/output state of the pins of the flash memory device with switching I/O structure shown in FIG. 8a.

### DETAILED DESCRIPTION OF THE PREFERRED EMBODIMENTS

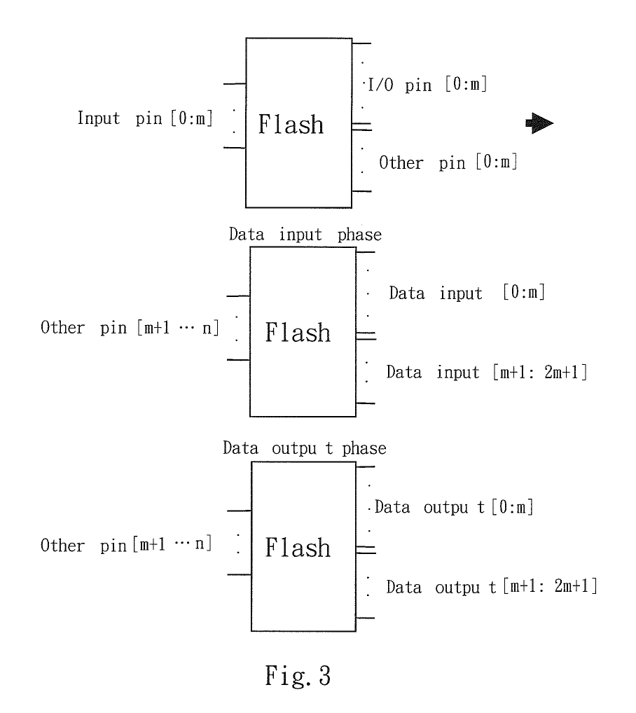

Please refer to FIG. 3, which shows a flash memory device with switching input/output (I/O) structure according to a first embodiment of the present invention. Herein, the flash memory device with switching I/O structure is generally denoted a numeral reference 3, and is also briefly referred to as the flash memory device.

During the I/O configuration for the flash memory device, the I/O structure maybe controlled through hardware by using logic control of the pins thereof; the I/O structure maybe configured through software by using some different codes, instructions, or commands; and the required I/O structure may be programmed through content addressable memory (CAM) access by using a non-volatile CAM cell.

As can be seen from FIG. 3, in the flash memory device of the present invention, during the data input phase, one other pin [0:m] serves as an input pin [m+1:2m+1]; and during the data output phase, the other pin [0:m] serves as an output pin [m+1:2m+1]. Therefore, the other pin [0:m] may always be used as an input pin [m+1:2m+1] and an output pin [m+1:2m+1] during the input phase and the output phase, respectively. As a result, during data input/data output, the flash memory device with switching I/O structure may have increased data input rate and data output rate, respectively.

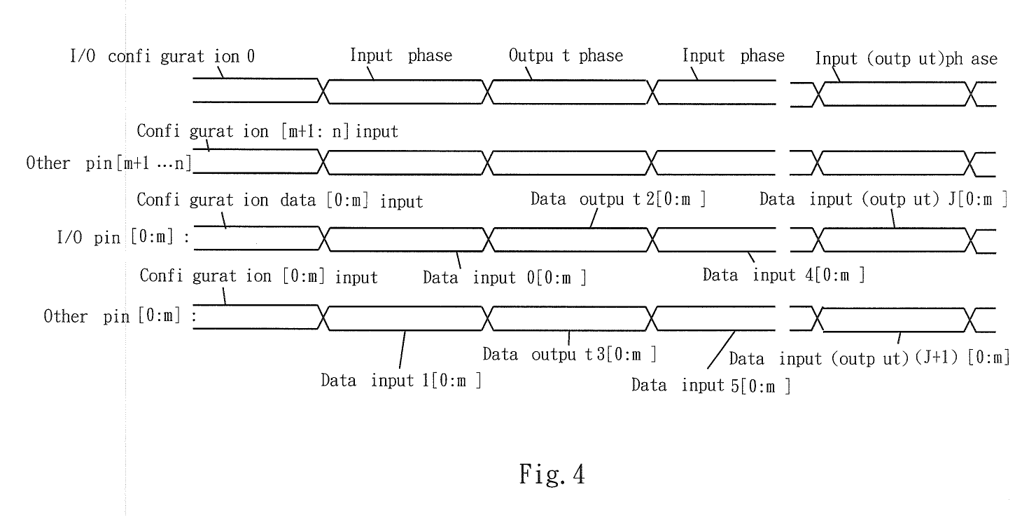

FIG. 4 is a phase sequence diagram showing the data input/output state of the pins of the flash memory device of FIG. 3. As can be seen from FIG. 4, after the I/O configuration, the first phase in the phase sequence is an input phase. During the input phase, the I/O pin [0:m] inputs data. Meanwhile, the other pin [0:m] serves as an input pin [m+1:2m+1] to input data, too. Therefore, the data input rate is multiplied. Thereafter, during the output phase, the I/O pin [0:m] outputs data. Meanwhile, the other pin [0:m] serves as an output pin [m+1:2m+1] to output data, too. Therefore, the data output rate is multiplied. The vector widths [0:m] and [m+1:2m+1] are the same with each other.

After the input/output structure has been configured, the switched other pin [0:m] of the flash memory device may start the data input/output immediately after the flash memory device is started to operate, without the need of waiting for several input/output phases.

During a specific phase, if the other pin [0:m] is not in use, the other pin [0:m] may be configured as an input pin [m+1:2m+1] or an output pin [m+1:2m+1]. During the data input phase, the other pin [0:m] may be configured as an input pin [m+1:2m+1] to thereby increase the data input rate. And, during the data output phase, the other pin [0:m] may be configured as an output pin [m+1:2m+1]. Therefore, the other pin [0:m] can be used not only as an input pin, but also an output pin to thereby double the data input rate and the data output rate. The vector widths [0:m] and [m+1:2m+1] are the same with each other.

FIG. 3 only illustrates one embodiment of the flash memory device with switching I/O structure 3 capable of doubling data input rate and data output rate. If it is desired to have even higher data I/O rate during the data input/output phase, simply configure more other pins as input pins or output pins. Since the latter case employs the same principle and technique as those shown in FIG. 3, it is not described in details herein.

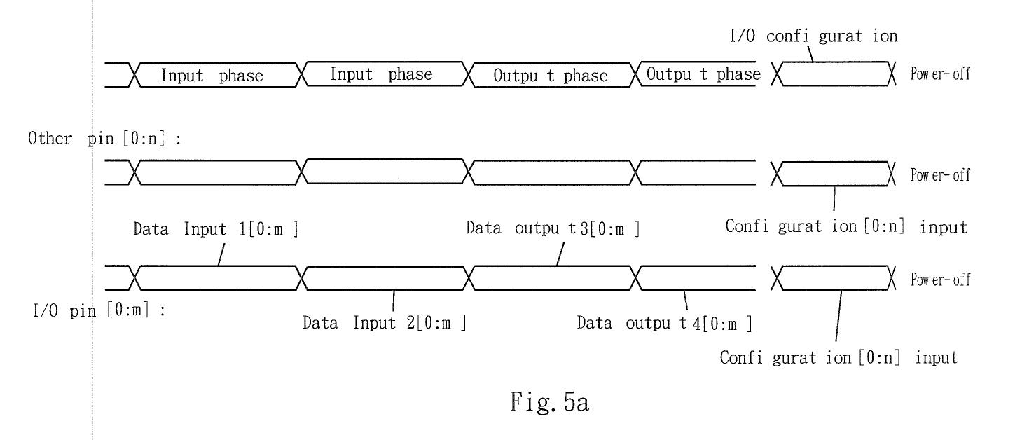

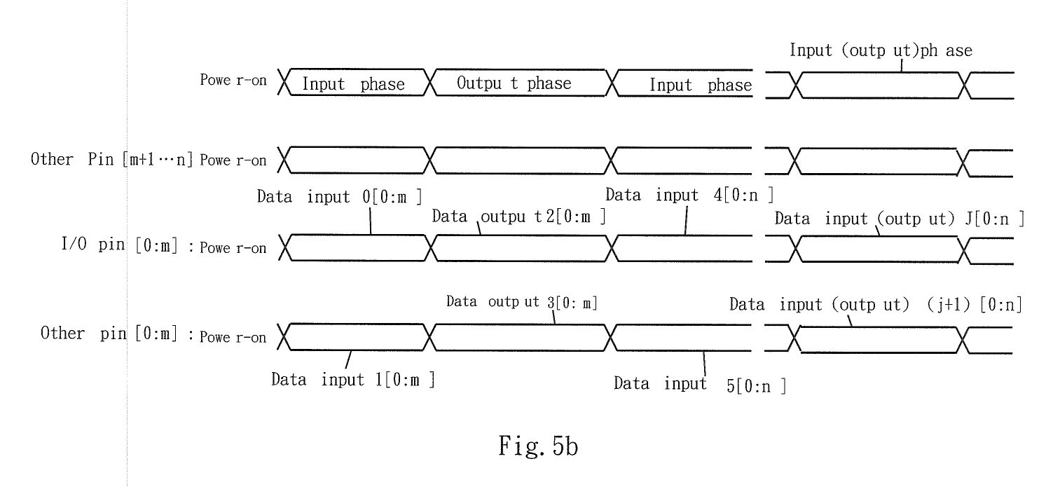

FIG. 5a is a phase sequence diagram showing the switching I/O structure of the flash memory device shown in FIG. 3 is configured through the content addressable memory (CAM) access. As can be seen from FIG. 5a, before the flash memory device is ready for use, first configure the I/O structure thereof at the time of testing or writing in the flash memory device, and use the non-volatile flash memory cell to record down the I/O configuration. After the power-off and the power-on procedures, the configured I/O structure may be maintained. During the I/O configuration at testing or writing in, the I/O pin [0:m] is configured as an input pin [0:m], and one other pin [0:n] is configured as an input pin [0:n].

FIG. 5b is a phase sequence diagram showing the data input/output state of the pins of the flash memory device of FIG. 5a. As can be seen from FIG. 5b, when the flash memory device is powered on, the first phase in the phase sequence is an input phase. During this input phase, the I/O pin [0:m] inputs data. Meanwhile, the other pin [0:m] configured as an input pin [m+1:2m+1] also inputs data. Therefore, the data input rate is multiplied. Thereafter, during the data output phase, the I/O pin [0:m] outputs data. Meanwhile, the other pin [0:m] configured as an output pin [m+1:2m+1] also outputs data. Therefore, the data output rate is multiplied. The vector widths [0:m] and [m+1:2m+1] are the same with each other.

The switched other pin [0:m] of the flash memory device may start the data input/output immediately after the flash memory device is started to operate, without the need of waiting for several input/output phases.

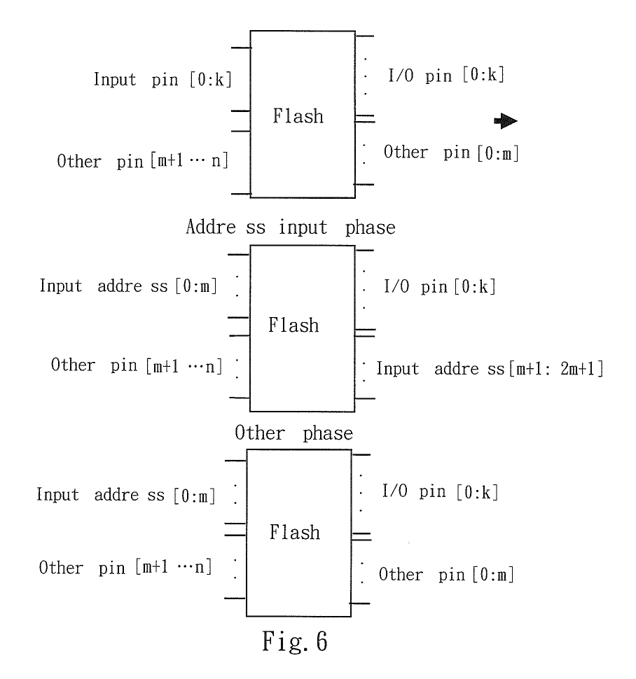

FIG. 6 is a conceptual view showing a flash memory device with switching input/output (I/O) structure according to a second embodiment of the present invention. Herein, the flash memory device with switching I/O structure is generally denoted a numeral reference 3, and is also briefly referred to as the flash memory device. During the I/O configuration for the flash memory device, the I/O structure may be controlled through hardware by using logic control of the pins thereof; the I/O structure may be configured through software by using some different codes, instructions, or commands; and the required I/O structure may be programmed through CAM access by using a non-volatile CAM cell.

As can be seen from FIG. 6, when the input data rate is limited to a certain rate, during the address input phase, the input pin [0:m] inputs addresses, and meanwhile, one other pin [0:m] may be used as an input pin [m+1:2m+1] for inputting addresses. Therefore, the address input rate is multiplied. That is, when the other pin [0:m] is configured as an address input pin [m+1:2m+1], the address input rate is multiplied during the address input phase. During other phases, such as the data input phase and the data output phase, the other pin [0:m] is still used as other pin without inputting/outputting data. Vector widths [0:m] and [m+1:2m+1] are the same with each other.

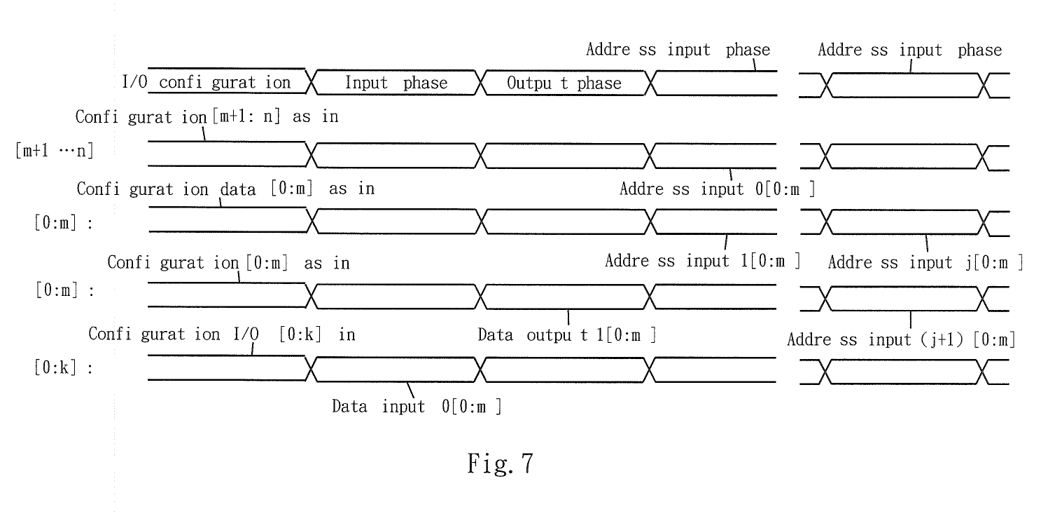

FIG. 7 is a phase sequence diagram for showing the data input/output state of the pins of the flash memory device shown in FIG. 6. As can be seen from FIG. 7, after the I/O configuration, the first phase in the phase sequence is an input phase. During the input phase, the I/O pin [0:m] inputs data. Then, during the following output phase, the I/O pin [0:m] outputs data. The vector widths [0:m] and [m+1:2m+1] are the same with each other.

During other phases, such as the data input phase and the data output phase, if the other pin [0:m] is not in use, it still functions as other pin without inputting/outputting data.

FIG. 6 only illustrates another embodiment of the flash memory device with switching I/O structure 3 capable of doubling the address input rate. If it is desired to have even higher address input rate during the address input phase, simply configure more other pins as input pins. Since the latter case employs the same principle and technique as those shown in FIG. 6, it is not described in details herein.

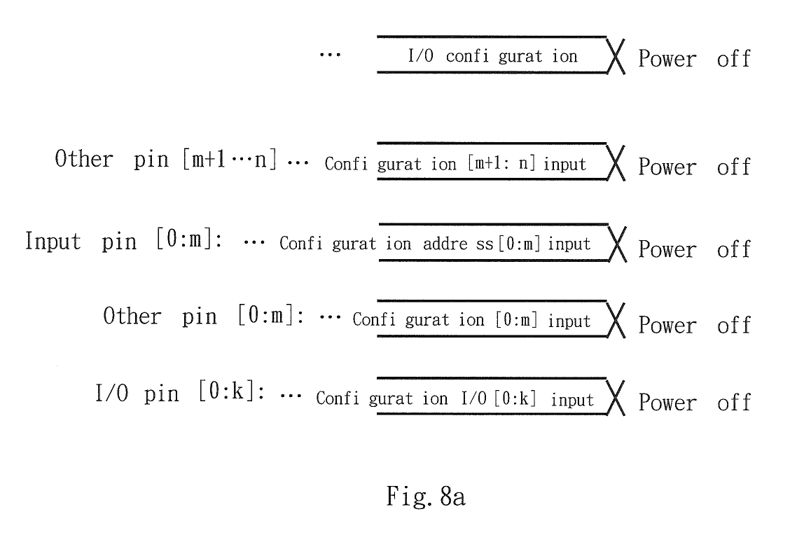

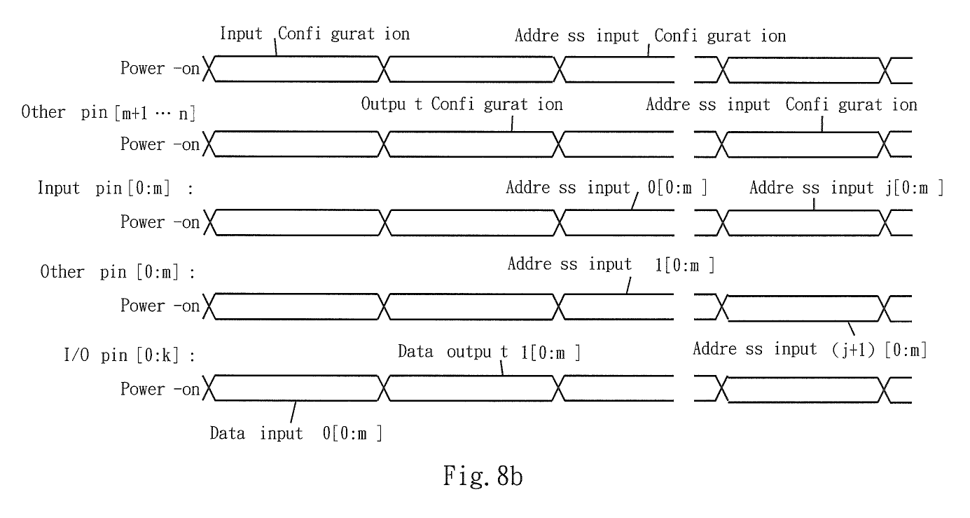

FIG. 8a is a phase sequence diagram showing the switching I/O structure of the flash memory device shown in FIG. 6 is configured using the content addressable memory (CAM) access. As can be seen from FIG. 8a, before the flash memory device is ready for use, first configure the I/O structure thereof at the time of testing or writing in the flash memory device, and use the non-volatile flash memory cell to record down the I/O configuration. After the power-off and the power-on procedures, the configured I/O structure may be maintained. During the I/O configuration at testing or writing in, the input pin [0:m] is configured as an address input pin [0:m], the I/O pin [0:k] is a data input/output pin [0:k], and one other pin [0:m] is configured as an address input pin [0:m].

FIG. 8b is a phase sequence diagram showing the data input/output state of the pins of the flash memory device of FIG. 8a. As can be seen from FIG. 8b, when the flash memory device is powered on, the first phase in the phase sequence is an input phase. During this data input phase, the pin [0:m] of the I/O pin [0:k] inputs data. Then, during the data output phase, the pin [0:m] of the I/O pin [0:k] outputs data. Thereafter, during the address input phase, the input pin [0:m] inputs addresses. Meanwhile, during the same address input phase, the other pin [0:m] is also used as address input pinto input addresses. Therefore, the address input rate is multiplied.

From the above-described embodiments, it is understood the present invention is a flash memory device with switching I/O structure for applying in flash memory products, so that, depending on actual need for input and/or output pins, other pins may be flexibly switched to input, output, or bi-directional pins via software and/or hardware and/or CAM access. As a result, the data input and/or output rate may be changed through switching the I/O structure. The flash memory device with switching I/O structure according to the present invention provides at least the following advantages:
1. In the other pins of the flash memory device with switching I/O structure according to the present invention, the switched other pins may start data input/output immediately after the flash memory is started to operate, without the need of waiting for several input/output phases.
2. The other pins may be flexibly switched to input, output, or bi-directional pins, and the data input and/or output rate may be changed through switching the I/O structure.

What is claimed is:

1. A flash memory device with switching input/output structure, comprising:
at least one memory element;
at least one input, output, or bi-directional pin for inputting/outputting data to/from the flash memory; and
at least one other pin that may be an input, an output, or a bi-directional pin;
wherein, the at least one other pin may be switched to an input pin, an output pin, a bi-directional pin, or one other pin.

2. The flash memory device as claimed in claim 1, wherein the other pin may be switched to an input pin, an output pin, a bi-directional pin, or one other pin through software, hardware, or content addressable memory (CAM) access.

3. The flash memory device as claimed in claim 2, wherein, with the CAM access, the memory element is addressed to a plurality of blocks, and the addresses in the memory element are corresponded to different blocks utilizing control logic.

4. The flash memory device as claimed in claim 1, wherein, the number of other pins for switching is from 1 to 10.

5. The flash memory device as claimed in claim 1, wherein, the number of different input/output structures that may be obtained by switching the at least one other pin is the original number of the other pins multiplied by 2ⁿ, where n is from −10 to 10; and wherein the data may be input to/output from the flash memory at a rate changeable within a range from 1 to 10 times of an original data input/output rate.

6. The flash memory device as claimed in claim 1, wherein the at least one other pin may be switched at a frequency of more than one time, and may be switched while the flash memory device is in use or is powered off.

7. A method of automatically switching other pins on a flash memory to input/output pins, comprising the steps of:
according to the requirements of a user system to which the flash memory is connected, writing the pin state to be switched to into the flash memory while the flash memory is in a power-off state; and
connecting the flash memory to the user system, and, with the pin state to be switched to having been written into the flash memory in advance, the pin is automatically switched to a bus state required by the system device.

8. The switching method as claimed in claim 7, wherein the other pin may be switched to an input pin, an output pin, a bi-directional pin, or one other pin through software, hardware, or content addressable memory (CAM) access.

9. The switching method as claimed in claim 7, wherein, with the CAM access, the memory element is addressed to a plurality of blocks, and the addresses in the memory element are corresponded to different blocks utilizing control logic.

10. The switching method as claimed in claim 7, wherein, the number of other pins for switching is from 1 to 10.

11. The switching method as claimed in claim 7, wherein, the number of different input/output structures that may be obtained by switching the at least one other pin is the original number of the other pins multiplied by 2ⁿ, where n is from −10 to 10; and wherein the data may be input to/output from the flash memory at a rate changeable within a range from 1 to 10 times of an original data input/output rate.
